(19) United States
(12) Patent Application Publication
(10) Pub. No.: US 2026/0072112 A1
(43) Pub. Date: Mar. 12, 2026

(54) Undersampled Point Restoration Method, Device and Magnetic Resonance Imaging System in Magnetic Resonance Imaging

(71) Applicant: Siemens Healthineers AG, Forchheim (DE)

(72) Inventors: Qiong Zhang, Shenzhen (CN); Xi Chen, Shenzhen (CN)

(73) Assignee: Siemens Healthineers AG, Forchheim (DE)

(21) Appl. No.: 19/324,385

(22) Filed: Sep. 10, 2025

(30) Foreign Application Priority Data
Sep. 10, 2024 (CN) 202411268266.4

(51) Int. Cl. G01R 33/561; G01R 33/56; G01R 33/58

(52) U.S. Cl. CPC G01R 33/561; G01R 33/5608; G01R 33/583

(57) ABSTRACT

The disclosure is directed to an undersampled point restoration method, device and magnetic resonance imaging system in magnetic resonance imaging. The method may include, during magnetic resonance scanning of an imaging subject, acquiring magnetic resonance signals of each channel by an undersampling mode and respectively placing the acquired magnetic resonance signals of each channel into the K-space of the each channel; and for any undersampled point in the K-space of each channel of the imaging subject, restoring the undersampled point by performing high-order interpolation on data points surrounding the undersampled point. Aspects improve the accuracy of restoring undersampled points in MR imaging, thereby further enhancing the quality of MR images.

### CROSS REFERENCE TO RELATED APPLICATIONS

This patent application claims priority to Chinese Patent Application No. 202411268266.4, filed Sep. 10, 2024, which is incorporated herein by reference in its entirety.

### BACKGROUND

### Technical Field

The present disclosure relates to the technical field of medical imaging, particularly to an undersampled point restoration method, device, and magnetic resonance imaging system in magnetic resonance imaging.

### Related Art

In MR (Magnetic Resonance) imaging, in order to accelerate acquisition speed, undersampling is usually employed when acquiring K-space data; however, if the undersampled K-space data are directly used for image reconstruction, image aliasing will occur; therefore, it is necessary to perform data restoration on the undersampled data before image reconstruction.

FIG. 1 is a simple schematic diagram of signal acquisition and image reconstruction in conventional MR imaging. In the figure, 111 is the fully sampled K-space data, 112 is the image obtained when 111 is subjected to image reconstruction; 121 is the undersampled K-space data, 122 is the image obtained when 121 is subjected to image reconstruction, and significant image aliasing can be observed in 122; 123 is the K-space data obtained after restoring the undersampled points in 121, and 124 is the image obtained when 123 is subjected to image reconstruction, and it can be seen that no image aliasing is observed in 124.

When the GRAPPA (GeneRalized Autocalibrating Partially Parallel Acquisitions) method is used for image reconstruction, undersampled points in K-space are usually restored by performing first-order interpolation on sampled points within the neighborhood, and the interpolation factors are calculated from reference data, the reference data also being called ACS (Auto-Calibrating Signal).

In two-dimensional MR imaging, the restoration formula for undersampled points in K-space is as shown in the formula (1) below:

$$y = {Σ}_{k = 1}^{K} {Σ}_{j = 1}^{M} {Σ}_{i = 1}^{N} {W}_{i j k} {x}_{i j k} \qquad ( 1 )$$

In the figure, y is the restored value of any undersampled point in K-space, xᵢⱼₖ is the signal value of any data point within the neighborhood of y in K-space, W ijk is the interpolation factor of xᵢⱼₖ, i represents the readout dimension, N is the size of the neighborhood of y in the readout dimension, j represents the phase-encoding dimension, M is the size of the neighborhood of y in the phase-encoding dimension, k represents the channel or coil dimension, and K is the size of the neighborhood of y in the channel or coil dimension.

FIG. 2 is a schematic diagram of restoring undersampled points in K-space in conventional two-dimensional imaging. In the figure, 211, 221, and 231 are the K-space data of channels 1, 2, and 3, respectively. In K-space, the horizontal direction is the readout direction, and the vertical direction is the phase-encoding direction, and along the phase-encoding direction, one line is sampled for every other line. As shown in FIG. 2, 201 indicates a sampled point, and 202 indicates an undersampled point. Taking the restoration of an undersampled point within 221 as an example, assume that the green-marked point within 222 is the undersampled point to be restored, and the interpolation range, or the neighborhood of the undersampled point to be restored, is indicated by 212 (the interpolation range on channel 1), 222 (the interpolation range on channel 2), and 232 (the interpolation range on channel 3). By performing first-order interpolation on the sampled points within 212, 222, and 232, the undersampled point to be restored can be restored. In the figure, 233 is ACS data, and the interpolation factors can be calculated from the fully sampled data within 233.

Three-dimensional MR imaging has an additional slice dimension compared with two-dimensional MR imaging, and therefore, in three-dimensional MR imaging, the restoration formula for undersampled points in K-space is as shown in the formula (2) below:

$$y = {Σ}_{k = 1}^{K} {Σ}_{h = 1}^{H} {Σ}_{j = 1}^{M} {Σ}_{i = 1}^{N} {W}_{i j h k} {x}_{i j h k} \qquad ( 2 )$$

In the formula, y is the restored value of any undersampled point in K-space, xᵢⱼₕₖ is the signal value of any data point within the neighborhood of y in K-space, Wᵢⱼₕₖ is the interpolation factor of xᵢⱼₕₖ, i represents the readout dimension, N is the size of the neighborhood of y in the readout dimension, j represents the phase-encoding dimension, M is the size of the neighborhood of y in the phase-encoding dimension, h represents the slice dimension, H is the size of the neighborhood of y in the slice dimension, k represents the channel or coil dimension, and K is the size of the neighborhood of y in the channel or coil dimension.

In practical applications, formulas (1) and (2) are usually simplified and expressed as:

$$y = {\sum }_{p = 1}^{P} {W}_{p} {x}_{p} \qquad ( 3 )$$

In the formula, y is the restored value of any undersampled point in K-space, xₚ is the signal value of the p-th data point within the neighborhood of y in K-space, Wₚ is the interpolation factor of xₚ, p represents the index of data points within the neighborhood of y, and P is the total number of data points within the neighborhood of y. For two-dimensional MR imaging, P=N*M*K, and for three-dimensional MR imaging, P=N*M*H*K wherein, Nis the size of the neighborhood of y in the readout dimension, M is the size of the neighborhood of y in the phase-encoding dimension, K is the size of the neighborhood of y in the channel or coil dimension, and H is the size of the neighborhood of y in the slice dimension.

In practical applications, an interpolation neighborhood for an undersampled point is usually selected empirically; for example, for each undersampled point in a two-dimensional K-space, the size of its neighborhood in the readout dimension is 5 and the size in the phase-encoding dimension is 3.

The existing method that restores undersampled points in K-space by first-order interpolation has a disadvantage, which is that, when this method is used for image reconstruction, artifacts will appear in the reconstructed image.

### BRIEF DESCRIPTION OF THE DRAWINGS/FIGURES

The accompanying drawings, which are incorporated herein and form a part of the specification, illustrate the embodiments of the present disclosure and, together with the description, further serve to explain the principles of the embodiments and to enable a person skilled in the pertinent art to make and use the embodiments.

FIG. 1 shows an example of signal acquisition and image reconstruction in conventional MR imaging.

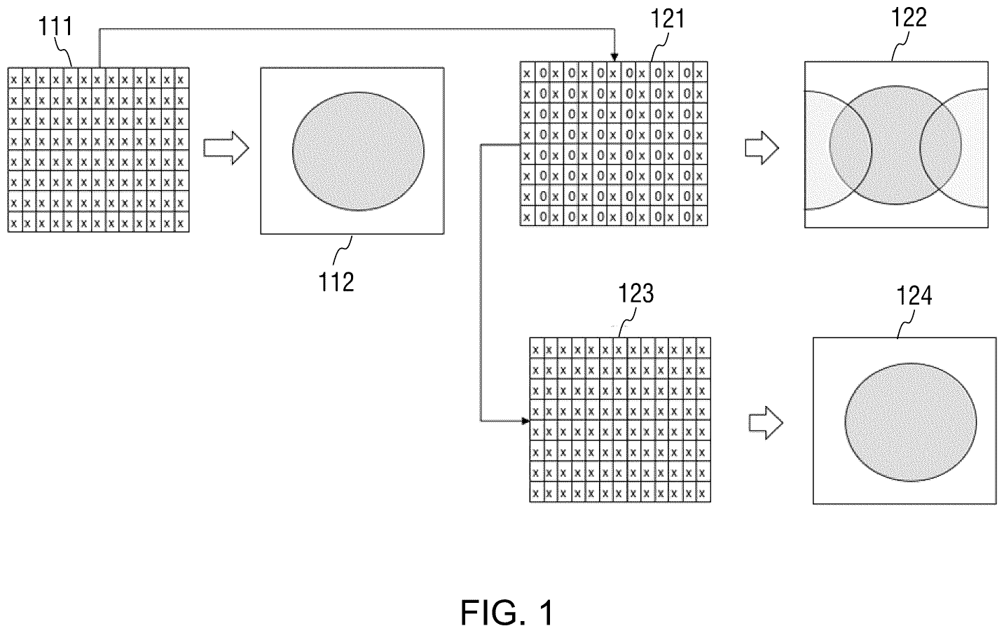

FIG. 2 shows a restoration of undersampled points in K-space in conventional two-dimensional imaging.

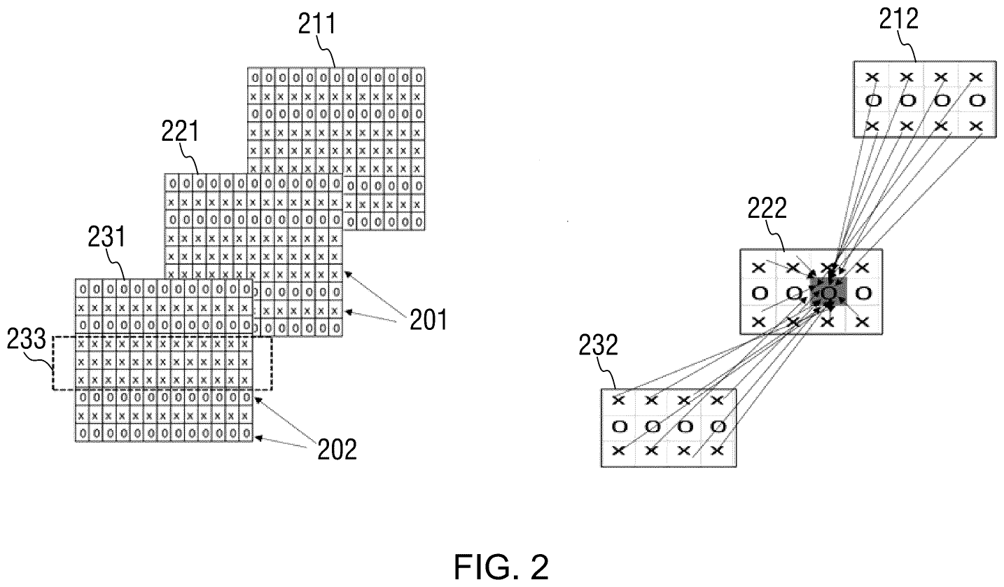

FIG. 3 is a flowchart of an undersampled point restoration method in MR imaging according to an exemplary embodiment of the disclosure.

FIGS. 4A-4C are schematic diagrams of the analysis process according to exemplary embodiments of the disclosure, which ensures aᵢ accuracy by increasing the contribution of points located outside the interpolation range.

FIG. 5 is an example of an application of the present disclosure in which a brain MR image is used as a reference, combined with a simulated coil map, to verify the effectiveness of exemplary embodiments of the present disclosure.

FIG. 6 is an undersampled point restoration device according to one or more exemplary embodiments of the present disclosure.

The exemplary embodiments of the present disclosure will be described with reference to the accompanying drawings. Elements, features and components that are identical, functionally identical and have the same effect are—insofar as is not stated otherwise—respectively provided with the same reference character.

### DETAILED DESCRIPTION

In the following description, numerous specific details are set forth in order to provide a thorough understanding of the embodiments of the present disclosure. However, it will be apparent to those skilled in the art that the embodiments, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring embodiments of the disclosure. The connections shown in the figures between functional units or other elements can also be implemented as indirect connections, wherein a connection can be wireless or wired. Functional units can be implemented as hardware, software or a combination of hardware and software.

In this context, on the one hand, the embodiments of the present disclosure propose an undersampled point restoration method and device in MR imaging to improve the accuracy of undersampled point restoration in MR imaging; on the other hand, an MR imaging system is proposed to improve the accuracy of undersampled point restoration in MR imaging.

An undersampled point restoration method in magnetic resonance imaging, the method comprising:
during magnetic resonance scanning of an imaging subject, acquiring magnetic resonance signals of each channel by an undersampling mode and respectively placing the acquired magnetic resonance signals of each channel into a K-space of each channel;
for any undersampled point in the K-space of each channel of the imaging subject, restoring the undersampled point by performing high-order interpolation on data points surrounding the undersampled point.

The restoring of the undersampled point by performing high-order interpolation on data points surrounding the undersampled point may comprise: performing second-order interpolation on all reference data points of the undersampled point to obtain a restored signal value of the undersampled point. The reference data points may be data points located within a preset interpolation range.

The performing second-order interpolation on all reference data points of the undersampled point to obtain a restored signal value of the undersampled point may comprise:
constructing a quadratic function that takes any reference data point of the undersampled point as the independent variable and has a constant term of 0; and
using the signal value of each reference data point of the undersampled point as the independent-variable value of the quadratic function to substitute it into the quadratic function to obtain each quadratic function value, adding the obtained quadratic function values to obtain a restored signal value of the undersampled point; the preset interpolation range is a preset neighborhood of the undersampled point within the K-space of each channel.

During magnetic resonance scanning of an imaging subject, by an undersampling mode, the acquiring the magnetic resonance signals of each channel and respectively placing the acquired magnetic resonance signals of each channel into the K-space of the corresponding channel may further comprise: during magnetic resonance scanning of an imaging subject, acquiring auto-calibrating signals ACS of each channel by a full-sampling mode, and placing the acquired ACS of each channel into the K-space of the each channel.

A quadratic-term coefficient and a linear-term coefficient of the quadratic function are obtained as follows: in the K-space of each channel, select multiple ACS, and, for each selected ACS, construct a quadratic equation; form a set of quadratic equations from all the constructed quadratic equations; solve the set of quadratic equations to obtain the quadratic-term coefficient and the linear-term coefficient of the quadratic function.

The quadratic equation is constructed as follows: using each ACS within a preset neighborhood of the selected ACS as the independent-variable value of the quadratic function to substitute it into the quadratic function to obtain each quadratic function value, adding the obtained quadratic function values, and setting the sum thereof as equal to the selected ACS.

The performing second-order interpolation on all reference data points of the undersampled point to obtain a restored signal value of the undersampled point may comprise:
constructing a function, the function including: a linear term that takes any first-type reference data point of the undersampled point as the independent variable; a linear term that takes any second-type reference data point of the undersampled point as the independent variable; and a quadratic term that takes the product of any first-type reference data point and any second-type reference data point of the undersampled point as the independent variable;
adding the above two linear terms and the one quadratic term to obtain the function; and
forming pairwise combinations of all first-type reference data points and all second-type reference data points of the undersampled point, substituting the signal value of the first-type reference data point and the signal value of the second-type reference data point of each combination into the function, respectively, to obtain each function value, and adding the obtained function values to obtain a restored signal value of the undersampled point.

The preset interpolation range may comprise a preset first interpolation range and a preset second interpolation range, the first-type reference data point is a data point located within the preset first interpolation range, the preset first interpolation range is a preset neighborhood of the undersampled point within the K-space of each channel, the second-type reference data point is a data point located within the preset second interpolation range, and the preset second interpolation range is a region within the K-space of each channel excluding the preset neighborhood.

During magnetic resonance scanning of an imaging subject, by an undersampling mode, the acquiring the magnetic resonance signals of each channel and respectively placing the acquired magnetic resonance signals of each channel into the K-space of the corresponding channel may further comprise: during magnetic resonance scanning of an imaging subject, acquiring auto-calibrating signals ACS of each channel by a full-sampling mode, and placing the acquired ACS of each channel into the K-space of the each channel.

The coefficients of the two linear terms of the function and the coefficient of one quadratic term may be obtained as follows: selecting multiple ACS in the K-space of each channel, constructing a quadratic equation for each selected ACS; forming a set of quadratic equations from all constructed quadratic equations; solving the set of quadratic equations to obtain the coefficients of the two linear terms of the function and the coefficient of one quadratic term.

The quadratic equation may be constructed as follows: combining all ACS within the preset first interpolation range of the selected ACS with all ACS within the preset second interpolation range in pairs, substituting the two ACS of each combination into the function respectively to obtain each function value, adding the obtained function values, and setting the sum thereof as equal to the selected ACS.

An undersampled point restoration device in magnetic resonance imaging may comprise:
an acquisition module, which is used to: during magnetic resonance scanning of an imaging subject, by an undersampling mode, acquire the magnetic resonance signals of each channel and respectively place the acquired magnetic resonance signals of each channel into the K-space of the each channel; and
a restoration module, which is used to: for any undersampled point in the K-space of each channel of the imaging subject, restore the undersampled point by performing high-order interpolation on data points surrounding the undersampled point.

The restoration module may be configured to restore the undersampled point by performing high-order interpolation on data points surrounding the undersampled point. Performing the high-order interpolation may comprise performing second-order interpolation on all reference data points of the undersampled point to obtain a restored signal value of the undersampled point. The reference data points may be data points located within a preset interpolation range.

The restoration module may perform second-order interpolation on all reference data points of the undersampled point to obtain a restored signal value of the undersampled point. The restoration module may be configured to:
construct a quadratic function that takes any reference data point of the undersampled point as the independent variable and has a constant term of zero (0); and
use the signal value of each reference data point of the undersampled point as the independent-variable value of the quadratic function to substitute it into the quadratic function to obtain each quadratic function value, adding the obtained quadratic function values to obtain a restored signal value of the undersampled point; the preset interpolation range is a preset neighborhood of the undersampled point within the K-space of each channel.

The acquisition module may be further used to: during magnetic resonance scanning of an imaging subject, acquire auto-calibrating signals ACS of each channel by a full-sampling mode, and placing the acquired ACS of each channel into the K-space of the each channel.

The quadratic-term coefficient and the linear-term coefficient of the quadratic function in the restoration module may be obtained as follows: in the K-space of each channel, select multiple ACS, and, for each selected ACS, construct a quadratic equation; form a set of quadratic equations from all the constructed quadratic equations; solve the set of quadratic equations to obtain the quadratic-term coefficient and the linear-term coefficient of the quadratic function.

The restoration module may construct a quadratic equation for each selected ACS. The construction may include: using each ACS within a preset neighborhood of the selected ACS as the independent-variable value of the quadratic function to substitute it into the quadratic function to obtain each quadratic function value, adding the obtained quadratic function values, and setting the sum thereof as equal to the selected ACS.

The restoration module may perform second-order interpolation on all reference data points of the undersampled point to obtain a restored signal value of the undersampled point. The process may comprise:
constructing a function, the function including: a linear term that takes any first-type reference data point of the undersampled point as the independent variable; a linear term that takes any second-type reference data point of the undersampled point as the independent variable; and a quadratic term that takes the product of any first-type reference data point and any second-type reference data point of the undersampled point as the independent variable;
adding the above two linear terms and the one quadratic term to obtain the function; and
forming pairwise combinations of all first-type reference data points and all second-type reference data points of the undersampled point, substituting the signal value of the first-type reference data point and the signal value of the second-type reference data point of each combination into the function, respectively, to obtain each function value, and adding the obtained function values to obtain a restored signal value of the undersampled point.

The preset interpolation range may comprise a preset first interpolation range and a preset second interpolation range, the first-type reference data point is a data point located within the preset first interpolation range, the preset first interpolation range is a preset neighborhood of the undersampled point within the K-space of each channel, the second-type reference data point is a data point located within the preset second interpolation range, and the preset second interpolation range is a region within the K-space of each channel excluding the preset neighborhood.

The acquisition module may be further used to: during magnetic resonance scanning of an imaging subject, acquire auto-calibrating signals ACS of each channel by a full-sampling mode, and placing the acquired ACS of each channel into the K-space of each channel.

The coefficients of the two linear terms of the function and the coefficient of one quadratic term in the restoration module may be obtained by selecting multiple ACS in the K-space of each channel, constructing a quadratic equation for each selected ACS; forming a set of quadratic equations from all constructed quadratic equations; and solving the set of quadratic equations to obtain the coefficients of the two linear terms of the function and the coefficient of one quadratic term.

The restoration module constructs a quadratic equation for each selected ACS, comprising: forming pairwise combinations of all ACS within the preset first interpolation range of the selected ACS and all ACS within the preset second interpolation range, respectively substituting the two ACS of each combination into the function to obtain function values, adding the obtained function values, and setting the sum thereof as equal to the selected ACS, thereby obtaining a quadratic equation.

A magnetic resonance imaging system, the system comprising any one of the above-mentioned undersampled point restoration devices in magnetic resonance imaging.

In one or more of the exemplary embodiments of the present disclosure, for any undersampled point in the K-space of each channel of the imaging subject, the undersampled point is restored by performing high-order interpolation on data points surrounding the undersampled point, thereby improving the accuracy of undersampled point restoration in MR imaging and further enhancing the quality of MR images.

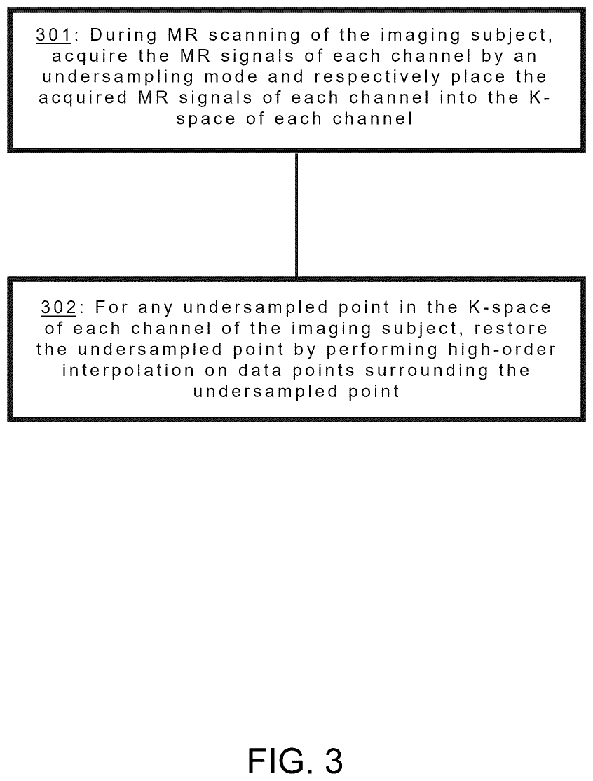

FIG. 3 is a flowchart of the undersampled point restoration method in MR imaging provided by an embodiment of the present disclosure. As shown in FIG. 3, the steps thereof are specifically as follows:

Step 301: During MR scanning of the imaging subject, acquire the MR signals of each channel by an undersampling mode and respectively place the acquired MR signals of each channel into the K-space of each channel.

Step 302: For any undersampled point in the K-space of each channel of the imaging subject, restore the undersampled point by performing high-order interpolation on data points surrounding the undersampled point.

After all undersampled points in K-space have been restored, an image-reconstruction method such as the GRAPPA method can be used to reconstruct the K-space data to obtain an MR image.

In an exemplary embodiment, in the present Step 302, the undersampled point is restored by performing high-order interpolation on data points surrounding the undersampled point, comprising: performing second-order interpolation on all reference data points of the undersampled point to obtain a restored signal value of the undersampled point, wherein the reference data points are data points located within a preset interpolation range.

In an exemplary embodiment, performing second-order interpolation on all reference data points of the undersampled point to obtain a restored signal value of the undersampled point may comprise:
constructing a quadratic function that takes any reference data point of the undersampled point as the independent variable and has a constant term of 0; and
using the signal value of each reference data point of the undersampled point as the independent-variable value of the quadratic function to substitute it into the quadratic function to obtain each quadratic function value and adding the obtained quadratic-function values to obtain the restored signal value of the undersampled point.

The preset interpolation range may be a preset neighborhood of the undersampled point within the K-space of each channel. Namely, the restoration of an undersampled point is achieved by the following formula (4):

$$y = {\sum }_{p = 1}^{P} ( {W}_{p} \cdot {x}_{p} + {H}_{p} \cdot {x}_{p}^{2} ) \qquad ( 4 )$$

In the formula, y is any undersampled point in the K-space of the imaging subject; xₚ is the p-th data point within the preset interpolation range of that undersampled point, 1≤p≤P; P is the number of data points within the preset interpolation range of that undersampled point; Wₚ is the coefficient of the linear term, and Hₚ is the coefficient of the quadratic term; for two-dimensional MR imaging, P=N*M*K, and for three-dimensional MR imaging, P=N*M*H*K, wherein N is the size of the preset interpolation range of y in the readout dimension, M is the size of the preset interpolation range of y in the phase-encoding dimension, K is the size of the preset interpolation range of y in the channel or coil dimension, and His the size of the preset interpolation range of y in the slice dimension. It can be seen that Wₚ·xₚ+Hₚ·xₚ² is a quadratic function that has a constant term of 0, Wₚ is the coefficient of the linear term, and Hₚ is the coefficient of the quadratic term.

In an exemplary embodiment, step 301 may further comprise: during MR scanning of an imaging subject, by a full-sampling mode, acquiring the ACS of each channel and placing the acquired ACS of each channel into the K-space of the each channel;

The quadratic-term coefficient and linear-term coefficient of the quadratic function (namely Hₚ and Wₚ in formula (4)) are obtained as follows: select multiple ACS in the K-space of each channel, construct a quadratic equation for each selected ACS, form a set of quadratic equations from all constructed equations, and solve the set to obtain the quadratic-term coefficient and the linear-term coefficient.

In an exemplary embodiment, constructing a quadratic equation is as follows: for each selected ACS, use each ACS within the preset neighborhood of the selected ACS as the independent-variable value of the quadratic function to substitute it into the quadratic function to obtain each quadratic function value, add the obtained quadratic function values, and set the sum thereof as equal to the selected ACS, thereby obtaining the quadratic equation.

In an exemplary embodiment, solving the set of quadratic equations may comprise: using a numerical algorithm to solve the set of quadratic equations. The numerical algorithm may include, for example, conjugate-gradient and other gradient-descent algorithms.

In an exemplary embodiment, performing second-order interpolation on all reference data points of the undersampled point to obtain the restored signal value of the undersampled point may comprise: constructing the following function that includes: a linear term that takes any first-type reference data point of the undersampled point as the independent variable; a linear term that takes any second-type reference data point of the undersampled point as the independent variable; and a quadratic term that takes the product of any first-type reference data point and any second-type reference data point of the undersampled point as the independent variable; adding the above two linear terms and the one quadratic term to obtain the function; forming pairwise combinations of all first-type reference data points and all second-type reference data points of the undersampled point, substituting the signal value of the first-type reference data point and the signal value of the second-type reference data point of each combination into the function respectively to obtain each function value, adding the obtained function values to obtain the restored signal value of the undersampled point;

In an exemplary embodiment, the preset interpolation range may comprise a preset first interpolation range and a preset second interpolation range, a first-type reference data point is a data point located within the preset first interpolation range, the preset first interpolation range is a preset neighborhood of the undersampled point within the K-space of each channel, and a second-type reference data point is a data point located within the preset second interpolation range, and the preset second interpolation range is a region within the K-space of each channel excluding the preset neighborhood.

Namely, the restoration of an undersampled point is achieved by the following formula (5):

$$y = {Σ}_{q = 1}^{Q} {Σ}_{p = 1}^{P} ( {W}_{p} \cdot {x}_{p} + {W}_{q} \cdot {x}_{q} + {H}_{p q} \cdot {x}_{p} \cdot {x}_{q} ) \qquad ( 5 )$$

In the formula, y is any undersampled point in the K-space of the imaging target; xₚ is the p-th data point within the first preset interpolation range of the undersampled point, 1≤p≤P, P is the number of data points within the first preset interpolation range; x_{q} is the q-th data point within the second preset interpolation range of the undersampled point, 1≤q≤Q, Q is the number of data points within the preset second interpolation range; Wₚ and W_{q} are coefficients of the linear terms, and H_{pq} is the coefficient of the quadratic term. It can be seen that Wₚ·xₚ is a linear term that takes xₚ as the independent variable, W_{q}·x_{q} is a linear term that takes x_{q} as the independent variable, and H_{pq}·xₚ·x_{q} is a quadratic term that takes the product of xₚ and x_{q} as the independent variable.

In an exemplary embodiment, step 301 may further comprise: during MR scanning of an imaging subject, by a full-sampling mode, acquiring the ACS of each channel and placing the acquired ACS of each channel into the K-space of each channel;

The coefficients of the two linear terms and the one quadratic term of the function (namely Wₚ, W_{q}, and H_{pq} in formula (5)) are obtained as follows: select multiple ACS in the K-space of each channel; for each selected ACS, construct a quadratic equation; form a set of quadratic equations from all constructed equations; solve the set of quadratic equations to obtain the coefficients of the two linear terms and the quadratic term of the function.

In an exemplary embodiment, the quadratic equation is constructed as follows:
for each selected ACS, form pairwise combinations of all ACS within the first preset interpolation range of the selected ACS and all ACS within the second preset interpolation range;
substitute the two ACS of each combination into the function respectively to obtain each function value; and
add the obtained function values and set the sum thereof as equal to the selected ACS to obtain the quadratic equation.

In an exemplary embodiment, solving the set of quadratic equations may comprise: using a numerical algorithm to solve the set of quadratic equations. The numerical algorithm may include, for example, conjugate-gradient and other gradient-descent algorithms.

In an exemplary embodiment, for any undersampled point in the K-space of each channel of the imaging subject, the undersampled point may be restored by performing high-order interpolation on data points surrounding the undersampled point, thereby indirectly increasing the contribution of data points outside the neighborhood of the undersampled point to restoration of the undersampled point, indirectly increasing the size of the reconstruction convolution kernel, improving the accuracy of undersampled-point restoration in MR imaging, and further enhancing the quality of MR images.

The above formulas (4) and (5) are obtained through the following process:

Assume f(s)(s∈[−L, L], L>0) is a continuous signal, then the Fourier transform of f(s) can be expressed as follows:

$${a}_{i} = {\int }_{- L}^{L} f ( s ) {e}^{- j \frac{π {k}_{i} s}{L}} d s \qquad ( 6 )$$

In the formula, kᵢ is the index or position of the i-th signal in the frequency domain, and i∈[−M, M], M>0.

For a digital image f(s)(s∈[−L, L], L>0), the Fourier series off(s) can be expressed as follows:

$$f ( s ) = \frac{1}{2 L} {Σ}_{n = - ∞}^{∞} ( {b}_{n} {e}^{j \frac{π n s}{L}} ) \qquad ( 7 )$$

In the formula, n is an integer, and bₙ is a coefficient.

Substituting the formula (7) into the formula (6) will get:

$${a}_{i} = {\int }_{- L}^{L} ( \frac{1}{2 L} {\sum }_{n = - ∞}^{∞} ( {b}_{n} {e}^{j \frac{π n s}{L}} {e}^{- j \frac{π {k}_{i} s}{L}} ) ) d s$$

$${a}_{i} = \frac{1}{2 L} {\sum }_{n = - ∞}^{∞} ( {b}_{n} {\int }_{- L}^{L} {e}^{j \frac{π n s}{L}} {e}^{- j \frac{π {k}_{i} s}{L}} ds )$$

$${a}_{i} = \frac{1}{2 L} {\sum }_{n = - ∞}^{∞} ( {b}_{n} {\int }_{- L}^{L} {e}^{j \frac{π s ( n - {k}_{i} )}{L}} ds )$$

$${a}_{i} = {\sum }_{n = - ∞}^{∞} ( {b}_{n} \cdot \frac{1}{2 L} {\int }_{- L}^{L} {e}^{j \frac{π s ( n - {k}_{i} )}{L}} d s )$$

Since

$$\frac{1}{2 L} {\int }_{- L}^{L} {e}^{j \frac{π s ( n - {k}_{i} )}{L}} d s = sin c ( π ( n - {k}_{i} ) )$$

so

$${a}_{i} = {\sum }_{n = - ∞}^{∞} ( {b}_{n} sin c ( π ( n - {k}_{i} ) ) )$$

Let Aᵢₙ=sinc(π(n−kg), then:

$${a}_{i} = {Σ}_{n = - ∞}^{∞} ( {A}_{i n} {b}_{n} ) \qquad ( 8 )$$

aᵢ can be regarded as the signal value of any data point in K-space, and from the formula (8), it can be seen that when aᵢ is unknown, aᵢ can be obtained by performing sinc interpolation using the surrounding points bₙ (Aᵢₙ is a sinc function).

In addition, according to n∈(−∞, ∞) in the formula (8), it can be seen that: aᵢ needs to be obtained by performing sinc interpolation on all other points in K-space; however, in practical applications, during image reconstruction, the reconstruction speed needs to be considered, and if sinc interpolation is performed on all other points in K-space, the computational load is large and the reconstruction speed is very slow, which is unacceptable in practical applications. Therefore, how can one, while reducing the number of points involved in sinc interpolation, ensure the accuracy of aᵢ? The inventor conceived that the accuracy of aᵢ can be ensured by increasing the contribution of points located outside the interpolation range (i.e., the preset neighborhood of aᵢ).

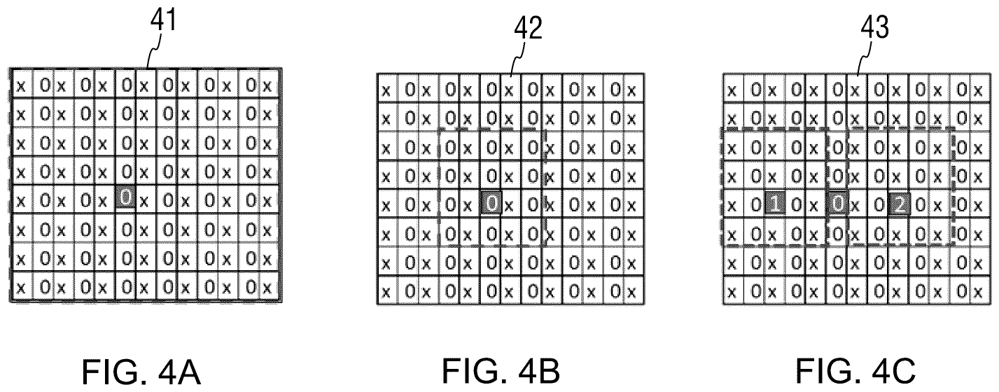

FIGS. 4A-4C are schematic diagrams of the analysis process in the present disclosure, wherein the accuracy of aᵢ is ensured by increasing the contribution of points located outside the interpolation range (i.e., the preset neighborhood of aᵢ). Here, 41, 42, and 43 are undersampled K-space data of a certain channel, and then:

As shown in FIG. 4A, based on signal restoration theory and the formula (8), it can be known that any point in K-space can be obtained by sinc interpolation of other points in K-space; for example, the green-marked undersampled point 0 in the undersampled K-space data 41 can be obtained by sinc interpolation of all other points in the undersampled K-space data 41 (that is, the points inside the red frame except the undersampled point) (in this example, it is assumed to be two-dimensional MR imaging and it is assumed that there is only one channel).

With reference to FIGS. 4B-4C, but in practical applications, considering the reconstruction speed, it is necessary to reduce the interpolation range. The reduced interpolation range is as shown by the red box in the undersampled K-space data 42. Because any point outside the interpolation range of the undersampled point 0, such as points 1 and 2 in the undersampled K-space data 43, can also be approximated by sinc interpolation of the points within their respective interpolation ranges, when calculating the undersampled point 0, if the contribution of points outside its interpolation range is considered, one can take into account the fact that the points outside its interpolation range are also obtained by sinc interpolation. At this time, a superposition of sinc functions occurs, and the superposition of sinc functions generates higher-order terms. Therefore, the restoration formula for undersampled points in K-space can be expressed as indicated by the above formula (5):

$$y = {Σ}_{q = 1}^{Q} {Σ}_{p = 1}^{P} ( {W}_{p} \cdot {x}_{p} + {W}_{q} \cdot {x}_{q} + {H}_{p q} \cdot {x}_{p} \cdot {x}_{q} ) \qquad ( 5 )$$

Specifically, when p=q, the above formula (5) becomes the above formula (4):

$$y = {\sum }_{p = 1}^{P} ( {W}_{p} \cdot {x}_{p} + {H}_{p} \cdot {x}_{p}^{2} ) \qquad ( 4 )$$

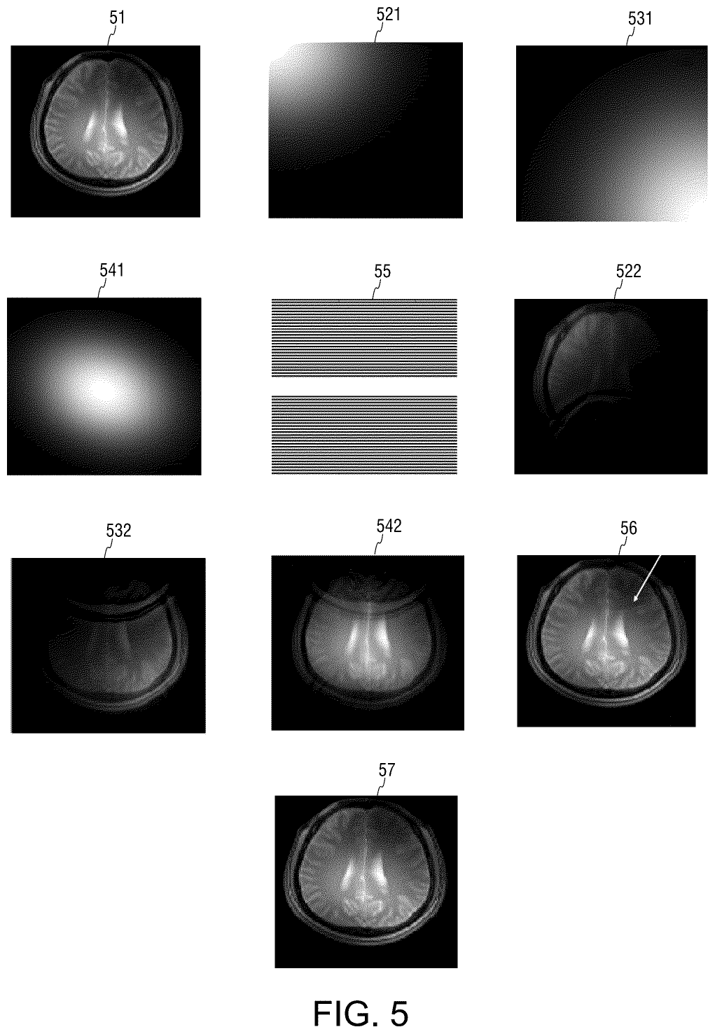

FIG. 5 is an example in an application of the present disclosure, where a brain MR image is used as a reference, which, in combination with simulated coil maps, verifies the effectiveness of adopting the embodiment of the present disclosure. In this example, 51 is a brain MR image reconstructed from fully sampled K-space data; 521, 531, and 541 are simulated coil maps with significantly different gains (the closer the coil is to the imaging subject, the greater the gain of its simulated coil map); 522 is a brain MR image obtained by undersampling the K-space data acquired by the coil a simulated by the simulated coil map 521 with the sampling mask shown in 55, and then reconstructing the resulting undersampled K-space data; 532 is a brain MR image obtained by undersampling the K-space data acquired by the coil b simulated by the simulated coil map 531 with the sampling mask shown in 55, and then reconstructing the resulting undersampled K-space data; 542 is a brain MR image obtained by undersampling the K-space data acquired by the coil c simulated by the simulated coil map 541 with the sampling mask shown in 55, and then reconstructing the resulting undersampled K-space data.

56 is a brain MR image obtained by reconstructing the image with the K-space data of coils a, b, and c after restoring the undersampled K-space data acquired by the coils a, b, and c using an existing first-order interpolation method, wherein the GRAPPA algorithm is used for the image reconstruction, and the interpolation range, that is, the neighborhood size, is P=3*5*3, wherein the first 3 is the neighborhood size in the readout dimension, 5 is the size in the phase-encoding dimension, and the second 3 is the size in the coil dimension.

57 is a brain MR image obtained by reconstructing the K-space data of the coils a, b, and c after restoring the undersampled K-space data acquired by the coils a, b, and c using the method provided in an embodiment of the present disclosure, wherein the GRAPPA algorithm is used for the image reconstruction, and the interpolation range, that is, the neighborhood size, is P=3*5*3, wherein the first 3 is the neighborhood size in the readout dimension, 5 is the size in the phase-encoding dimension, and the second 3 is the size in the coil dimension.

A comparison of 57 with 56 will find that the artifact indicated by the arrow in 56 disappears in 57, that is, the method provided by the embodiment of the present disclosure can reduce artifacts in MR images.

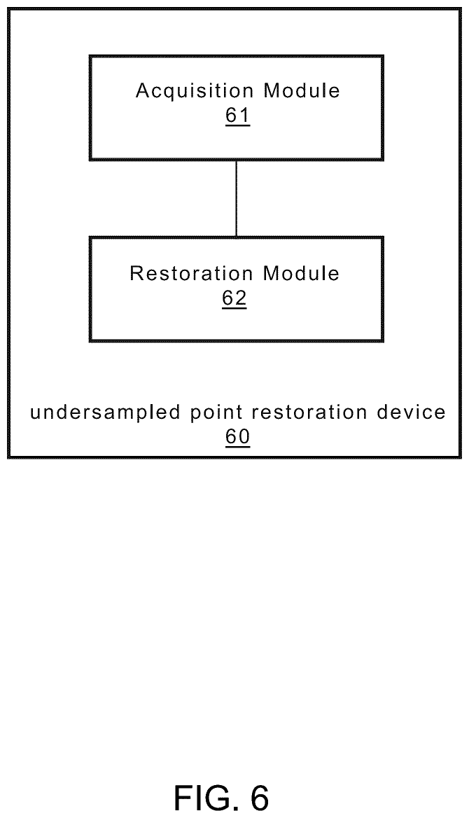

FIG. 6 is a schematic structural diagram of the undersampled point restoration device 60 in MR imaging provided by one embodiment of the present disclosure. As shown in FIG. 6, the device 60 may comprise an acquisition module 61 and a restoration module 62. In an exemplary embodiment, the device 60 may comprise processing circuitry that is configured to perform one or more operations and/or functions of the device 60. Additionally, or alternatively, one or more components (e.g., modules 61 and/or 62) may comprise processing circuitry that is configured to perform one or more respective operations and/or functions of the component(s).

The acquisition module (scanner) 61 may be configured to: during MR scanning of the imaging subject, acquire the MR signals of each channel by an undersampling mode and place the acquired MR signals of each channel into the K-space of the each channel.

The restoration module (restoration processor, controller) 62 may be configured to: for any undersampled point in the K-space of each channel of the imaging subject, restore the undersampled point by performing high-order interpolation on the data points surrounding the undersampled point. Additionally, or alternatively, the restoration module 62 may be configured to control the module 61 (and/or one more other components of the device 60) and/or the overall operation of the device 60.

In an exemplary embodiment, the restoration module 62 restores the undersampled point by performing high-order interpolation on the data points surrounding that undersampled point, comprising performing second-order interpolation on all reference data points of the undersampled point to obtain the restored signal value of the undersampled point, wherein the reference data points are those located within a preset interpolation range.

In an exemplary embodiment, the restoration module 62 performs second-order interpolation on all reference data points of the undersampled point to obtain the restored signal value of the undersampled point, comprising: constructing a quadratic function that takes any reference data point of the undersampled point as the independent variable and has the constant term 0; using the signal value of each reference data point of the undersampled point as the independent variable value to substitute it into the quadratic function to obtain each quadratic function value, and adding the obtained quadratic function values to obtain the restored signal value of the undersampled point; here, the preset interpolation range is the preset neighborhood of the undersampled point in the K-space of each channel.

In an exemplary embodiment, the acquisition module 61 is further used to: during MR scanning of the imaging subject, by a full-sampling mode, acquire the auto-calibration signals ACS of each channel and place the acquired ACS of each channel into the K-space of each channel.

Moreover, the quadratic-term coefficient and the linear-term coefficient of the quadratic function in the restoration module 62 are obtained as follows: select multiple ACS in the K-space of each channel, construct a quadratic equation for each selected ACS; combine all constructed quadratic equations into a set of quadratic equations; solve the set of quadratic equations to obtain the quadratic-term coefficient and the linear-term coefficient of the quadratic function.

In an exemplary embodiment, the restoration module 62 constructs a quadratic equation for each selected ACS, comprising: respectively using each ACS within the preset neighborhood of the selected ACS as the independent-variable value of the quadratic function to substitute it into the quadratic function to obtain each quadratic-function value; adding the obtained quadratic-function values, and setting the sum thereof as equal to the selected ACS, and thus obtaining a quadratic equation.

In an exemplary embodiment, the restoration module 62 solves the set of quadratic equations, comprising: using a numerical algorithm to solve the set of quadratic equations.

In an exemplary embodiment, the restoration module 62 performs second-order interpolation on all reference data points of the undersampled point to obtain the restored signal value of the undersampled point, comprising: constructing the following function that includes a linear term that takes any first-type reference data point of the undersampled point as the independent variable, a linear term that takes any second-type reference data point of the undersampled point as the independent variable, and a quadratic term that takes the product of any first-type reference data point and any second-type reference data point of the undersampled point as the independent variable; adding the above two linear terms and the one quadratic term to obtain the function; forming pairwise combinations of all first-type reference data points and all second-type reference data points of the undersampled point, substituting the signal value of the first-type reference data point and the signal value of the second-type reference data point of each combination respectively into the function to obtain each function value, and adding the obtained function values to obtain the restored signal value of the undersampled point; here, the preset interpolation range includes a preset first interpolation range and a preset second interpolation range, the first-type reference data points are data points located within the preset first interpolation range, the preset first interpolation range being a preset neighborhood of the undersampled point in the K-space of each channel, and the second-type reference data points are data points located within the preset second interpolation range, the preset second interpolation range being the region in the K-space of each channel outside the preset neighborhood.

In an exemplary embodiment, the acquisition module 61 is further used to: during MR scanning of the imaging subject, by a full-sampling mode, acquire the auto-calibration signals ACS of each channel and place the acquired ACS of each channel into the K-space of each channel.

The coefficient of each of the two linear terms and the coefficient the one quadratic term of the function in the restoration module 62 are obtained as follows: select multiple ACS in the K-space of each channel; for each selected ACS, construct a quadratic equation; form a set of quadratic equations from all the constructed quadratic equations; solve the set of quadratic equations to obtain the coefficient of each of the two linear terms and the coefficient of the one quadratic term of the function.

In an exemplary embodiment, the restoration module 62 constructs a quadratic equation for each selected ACS, comprising: forming pairwise combinations of all ACS within the preset first interpolation range of the selected ACS and all ACS within the preset second interpolation range; substituting the two ACS of each combination respectively into the function to obtain the function values; adding the obtained function values and setting the sum thereof as equal to the selected ACS, and thus obtaining a quadratic equation.

In an exemplary embodiment, the restoration module 62 solves the set of quadratic equations, comprising: using a numerical algorithm to solve the set of quadratic equations.

An embodiment of the present disclosure further provides an MR imaging system, which includes the undersampled point restoration device 60 in MR imaging as described in any of the above embodiments.

It should be noted that the undersampled point restoration method, device, and MR imaging system provided by the embodiments of the present disclosure can all be methods, devices, and systems used in medical imaging.

An embodiment of the present disclosure further provides a computer program product, comprising a computer program or instructions, the computer program or instructions, when executed by a processor, implement the steps of the undersampled point recovery method in MR imaging according to any one of the above embodiments.

An embodiment of the present disclosure further provides a computer-readable storage medium, the computer-readable storage medium storing instructions, which, when executed by a processor, can execute the steps of the undersampled point restoration method in MR imaging as described above. In practical applications, the computer-readable medium may be included in each device/apparatus/system in the above embodiments, or may exist independently without being fitted into the device/apparatus/system. Here, the instructions are stored in the computer-readable storage medium, and the stored instructions, when executed by the processor, can execute the steps of the above-mentioned undersampled point restoration method in MR imaging.

An embodiment of the present disclosure further provides an electronic device. The electronic device may include a processor with one or more processing cores, a memory with one or more computer-readable storage media, and a computer program stored in the memory and executable on the processor. When the program stored in the memory is executed, the above-mentioned undersampled point restoration method in MR imaging can be implemented.

Those skilled in the art will understand that features stated in the various embodiments and/or claims disclosed in the present application can be combined and/or integrated in various ways, even if such combinations or integrations are not clearly stated in the present application. In particular, without departing from the spirit and teaching of the present application, features stated in the various embodiments and/or claims of the present application can be combined and/or integrated in various ways, and all such combinations and/or integrations fall within the scope of disclosure of the present application.

Specific embodiments have been used herein to expound the principles and implementations of the present application, but the description of the embodiments above is merely intended to help understand the method of the present application and the core idea thereof, not to restrict the present application. Those skilled in the art may change a specific implementation and application scope, based on the idea, spirit and principles of the present application, and any modifications, equivalent replacements, improvements, etc., which are made by those skilled in the art should be included within the scope of protection of the present application.

To enable those skilled in the art to better understand the solution of the present disclosure, the technical solution in the embodiments of the present disclosure is described clearly and completely below in conjunction with the drawings in the embodiments of the present disclosure. Obviously, the embodiments described are only some, not all, of the embodiments of the present disclosure. All other embodiments obtained by those skilled in the art on the basis of the embodiments in the present disclosure without any creative effort should fall within the scope of protection of the present disclosure.

It should be noted that the terms “first”, “second”, etc. in the description, claims and abovementioned drawings of the present disclosure are used to distinguish between similar objects, but not necessarily used to describe a specific order or sequence. It should be understood that data used in this way can be interchanged as appropriate so that the embodiments of the present disclosure described here can be implemented in an order other than those shown or described here. In addition, the terms “include,” “comprise,” and “have,” and any variants thereof, are intended to cover non-exclusive inclusion. For example, a process, method, system, product or equipment comprising a series of steps or modules or units is not necessarily limited to those steps or modules or units which are clearly listed, but may comprise other steps or modules or units which are not clearly listed or are intrinsic to such processes, methods, products or equipment.

References in the specification to “one embodiment,” “an embodiment,” “an exemplary embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The exemplary embodiments described herein are provided for illustrative purposes, and are not limiting. Other exemplary embodiments are possible, and modifications may be made to the exemplary embodiments. Therefore, the specification is not meant to limit the disclosure. Rather, the scope of the disclosure is defined only in accordance with the following claims and their equivalents.

Embodiments may be implemented in hardware (e.g., circuits), firmware, software, or any combination thereof. Embodiments may also be implemented as instructions stored on a machine-readable medium, which may be read and executed by one or more processors. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact results from computing devices, processors, controllers, or other devices executing the firmware, software, routines, instructions, etc. Further, any of the implementation variations may be carried out by a general-purpose computer.

The various components described herein may be referred to as “modules,” “units,” or “devices.” Such components may be implemented via any suitable combination of hardware and/or software components as applicable and/or known to achieve their intended respective functionality. This may include mechanical and/or electrical components, processors, processing circuitry, or other suitable hardware components, in addition to or instead of those discussed herein. Such components may be configured to operate independently, or configured to execute instructions or computer programs that are stored on a suitable computer-readable medium. Regardless of the particular implementation, such modules, units, or devices, as applicable and relevant, may alternatively be referred to herein as “circuitry,” “controllers,” “processors,” or “processing circuitry,” or alternatively as noted herein.

For the purposes of this discussion, the term “processing circuitry” shall be understood to be circuit(s) or processor(s), or a combination thereof. A circuit includes an analog circuit, a digital circuit, data processing circuit, other structural electronic hardware, or a combination thereof. A processor includes a microprocessor, a digital signal processor (DSP), central processor (CPU), application-specific instruction set processor (ASIP), graphics and/or image processor, multi-core processor, or other hardware processor. The processor may be “hard-coded” with instructions to perform corresponding function(s) according to aspects described herein. Alternatively, the processor may access an internal and/or external memory to retrieve instructions stored in the memory, which when executed by the processor, perform the corresponding function(s) associated with the processor, and/or one or more functions and/or operations related to the operation of a component having the processor included therein.

In one or more of the exemplary embodiments described herein, the memory is any well-known volatile and/or non-volatile memory, including, for example, read-only memory (ROM), random access memory (RAM), flash memory, a magnetic storage media, an optical disc, erasable programmable read only memory (EPROM), and programmable read only memory (PROM). The memory can be non-removable, removable, or a combination of both.

A reference listing is provided below:
111 Fully sampled K-space data
112 Image obtained when image reconstruction is performed for 111
121 Undersampled K-space data
122 Image obtained when image reconstruction is performed for 121
123 K-space data obtained after restoring undersampled points in 121
124 Image obtained when image reconstruction is performed for 123
211 K-space data of channel 1
221 K-space data of channel 2
231 K-space data of channel 3
201 Sampled point
202 Undersampled point
212, 222, 232 Regions of the interpolation ranges on channels 1, 2, 3
233 ACS data
301-302 Steps
41, 42, 43 Undersampled K-space data of a certain channel
51 Brain MR image reconstructed using fully sampled K-space data
521, 531, 541 Simulated coil maps with significantly different gains
55 Sampling mask
522 A brain MR image obtained by undersampling the K-space data acquired by the simulated coil a of the simulated coil map 521 using the sampling mask shown by 55, and then performing an image reconstruction of the resulting undersampled K-space data
532 A brain MR image obtained by undersampling the K-space data acquired by the simulated coil b of the simulated coil map 531 using the sampling mask shown by 55 and then performing an image reconstruction of the resulting undersampled K-space data
542 A brain MR image obtained by undersampling the K-space data acquired by the simulated coil c of the simulated coil map 541 using the sampling mask shown by 55 and then performing an image reconstruction of the resulting undersampled K-space data
56 A brain MR image obtained by restoring the undersampled K-space data acquired by coils a, b, and c using an existing first-order interpolation method, and then performing an image reconstruction of the restored K-space data of coils a, b, and c
57 A brain MR image obtained by restoring the undersampled K-space data acquired by coils a, b, and c using the method provided in an embodiment of the present disclosure, and then performing an image reconstruction of the restored K-space data of coils a, b, and c
60 Undersampled point restoration device in MR imaging
61 Acquisition module
62 Restoration module

1. An undersampled point restoration method in magnetic resonance imaging, the method comprising:
during magnetic resonance scanning of an imaging subject, acquiring magnetic resonance signals of each channel by an undersampling mode and respectively placing the acquired magnetic resonance signals of each channel into K-space of each; and
for any undersampled point in K-space of each channel of the imaging subject, performing high-order interpolation on data points surrounding the undersampled point to restore the undersampled point.

2. The method as claimed in claim 1, wherein the restoring the undersampled point by performing high-order interpolation on data points surrounding the undersampled point comprises:
performing second-order interpolation on all reference data points of the undersampled point to obtain a restored signal value of the undersampled point, the reference data points being data points located within a preset interpolation range.

3. The method as claimed in claim 2, wherein the performing second-order interpolation on all reference data points of the undersampled point to obtain the restored signal value of the undersampled point comprises:
constructing a quadratic function that takes any reference data point of the undersampled point as an independent variable and has a constant term of zero; and
using a restored signal value of each reference data point of the undersampled point as the independent-variable value of the quadratic function to substitute the restored signal value of each reference data point into the quadratic function to obtain each quadratic function value, adding the obtained quadratic function values to obtain the restored signal value of the undersampled point, wherein the preset interpolation range is a preset neighborhood of the undersampled point within K-space of each channel.

4. The method as claimed in claim 3, wherein the acquiring magnetic resonance signals of each channel by the undersampling mode and respectively placing the acquired magnetic resonance signals of each channel into K-space of each channel further comprises:
acquiring auto-calibrating signals (ACS) of each channel by a full-sampling mode, and placing the acquired ACS of each channel into K-space of each channel; and
obtaining a quadratic-term coefficient and a linear-term coefficient of the quadratic function by:
in K-space of each channel, selecting multiple ACS, and, for each selected ACS, constructing a quadratic equation;
forming a set of quadratic equations from all the constructed quadratic equations; and
solve the set of quadratic equations to obtain the quadratic-term coefficient and the linear-term coefficient of the quadratic function.

5. The method as claimed in claim 4, wherein the construction of the quadratic equation comprises: using each ACS within a preset neighborhood of the selected ACS as the independent-variable value of the quadratic function to substitute the ACS within the preset neighborhood into the quadratic function to obtain each quadratic function value, adding the obtained quadratic function values to obtain a sum of quadratic function values, and setting the sum of quadratic function values as equal to the selected ACS.

6. The method as claimed in claim 2, wherein the performing second-order interpolation on all reference data points of the undersampled point to obtain the restored signal value of the undersampled point comprises:
setting a linear term that takes any first-type reference data point of the undersampled point as an independent variable; a linear term that takes any second-type reference data point of the undersampled point as an independent variable; and a quadratic term that takes the product of any first-type reference data point and any second-type reference data point of the undersampled point as an independent variable;
adding the linear term that takes any first-type reference data point of the undersampled point, linear term that takes any second-type reference data point of the undersampled point, and the one quadratic term to obtain a function; and
forming pairwise combinations of all first-type reference data points and all second-type reference data points of the undersampled point, substituting the signal value of the first-type reference data point and the signal value of the second-type reference data point of each combination into the function, respectively, to obtain each function value, and adding the obtained function values to obtain a restored signal value of the undersampled point,
wherein the preset interpolation range comprises a preset first interpolation range and a preset second interpolation range, the first-type reference data point is a data point located within the preset first interpolation range, the preset first interpolation range is a preset neighborhood of the undersampled point within the K-space of each channel, the second-type reference data point is a data point located within the preset second interpolation range, and the preset second interpolation range is a region within the K-space of each channel excluding the preset neighborhood.

7. The method as claimed in claim 6, wherein the acquiring magnetic resonance signals of each channel by the undersampling mode and respectively placing the acquired magnetic resonance signals of each channel into K-space of each channel further comprises:
acquiring auto-calibrating signals ACS of each channel by a full-sampling mode, and placing the acquired ACS of each channel into the K-space of each channel; and
obtaining coefficients of: the linear term that takes any first-type reference data point of the undersampled point, the linear term that takes any second-type reference data point of the undersampled point, and the quadratic term by: selecting multiple ACS in K-space of each channel; constructing a quadratic equation for each selected ACS; forming a set of quadratic equations from all constructed quadratic equations; and solving the set of quadratic equations to obtain the coefficients of the linear term that takes any first-type reference data point of the undersampled point, the linear term that takes any second-type reference data point of the undersampled point, and the quadratic term.

8. The method as claimed in claim 7, wherein constructing the quadratic equation comprises: combining all ACS within the preset first interpolation range of the selected ACS with all ACS within the preset second interpolation range in pairs, substituting the two ACS of each combination into the function respectively to obtain each function value, adding the obtained function values to obtain a sum of the function values, and setting the sum of the function values as equal to the selected ACS.

9. An undersampled point restoration device for magnetic resonance imaging, the device comprising:
an acquisition module configured to: during magnetic resonance scanning of an imaging subject, by an undersampling mode, acquire the magnetic resonance signals of each channel and respectively place the acquired magnetic resonance signals of each channel into K-space of each channel; and
a restoration module configured to: for any undersampled point in K-space of each channel of the imaging subject, perform high-order interpolation on data points surrounding the undersampled point to restore the undersampled point.

10. The device as claimed in claim 9, wherein the performance of the high-order interpolation comprises: performing second-order interpolation on all reference data points of the undersampled point to obtain a restored signal value of the undersampled point, wherein the reference data points are data points located within a preset interpolation range.

11. The device as claimed in claim 10, wherein the restoration module performs second-order interpolation on all reference data points of the undersampled point to obtain the restored signal value of the undersampled point, comprising:
constructing a quadratic function that takes any reference data point of the undersampled point as the independent variable and has a constant term of zero; and
using the signal value of each reference data point of the undersampled point as the independent-variable value of the quadratic function to substitute it into the quadratic function to obtain each quadratic function value, adding the obtained quadratic function values to obtain the restored signal value of the undersampled point, wherein the preset interpolation range is a preset neighborhood of the undersampled point within K-space of each channel.

12. The device as claimed in claim 11, wherein:
the acquisition module is configured to: during magnetic resonance scanning of an imaging subject, acquire auto-calibrating signals (ACS) of each channel by a full-sampling mode, and place the acquired ACS of each channel into K-space of each channel; and
the restoration module is configured to obtain a quadratic-term coefficient and a linear-term coefficient of the quadratic function by: in K-space of each channel, selecting multiple ACS, and, for each selected ACS, constructing a quadratic equation; forming a set of quadratic equations from all the constructed quadratic equations; and solving the set of quadratic equations to obtain the quadratic-term coefficient and the linear-term coefficient of the quadratic function.

13. The device as claimed in claim 12, wherein the restoration module is configured to construct the quadratic equation for each selected ACS by:
using each ACS within a preset neighborhood of the selected ACS as an independent-variable value of the quadratic function to substitute each ACS within the preset neighborhood of the selected ACS into the quadratic function to obtain each quadratic function value, adding the obtained quadratic function values, and setting the sum thereof as equal to the selected ACS.

14. The device as claimed in claim 10, wherein the restoration module is configured to perform the second-order interpolation on all reference data points of the undersampled point to obtain the restored signal value of the undersampled point by:
setting a linear term that takes any first-type reference data point of the undersampled point as an independent variable; a linear term that takes any second-type reference data point of the undersampled point as an independent variable; and a quadratic term that takes the product of any first-type reference data point and any second-type reference data point of the undersampled point as an independent variable;
adding the linear term that takes any first-type reference data point of the undersampled point, the linear term that takes any second-type reference data point of the undersampled point, and the quadratic term to obtain a function; and
forming pairwise combinations of all first-type reference data points and all second-type reference data points of the undersampled point, substituting the signal value of the first-type reference data point and the signal value of the second-type reference data point of each combination into the function, respectively, to obtain each function value, and adding the obtained function values to obtain a restored signal value of the undersampled point,
wherein the preset interpolation range comprises a preset first interpolation range and a preset second interpolation range, the first-type reference data point is a data point located within the preset first interpolation range, the preset first interpolation range is a preset neighborhood of the undersampled point within the K-space of each channel, the second-type reference data point is a data point located within the preset second interpolation range, and the preset second interpolation range is a region within the K-space of each channel excluding the preset neighborhood.

15. The device as claimed in claim 14, wherein:
the acquisition module is further configured to: during magnetic resonance scanning of an imaging subject, acquiring auto-calibrating signals (ACS) of each channel by a full-sampling mode, and placing the acquired ACS of each channel into the K-space of each channel; and
the restoration module is configured to obtain coefficients of the linear term that takes any first-type reference data point of the undersampled point, the linear term that takes any second-type reference data point of the undersampled point, and the quadratic term by: selecting multiple ACS in K-space of each channel, constructing a quadratic equation for each selected ACS, forming a set of quadratic equations from all constructed quadratic equations, and solving the set of quadratic equations to obtain the coefficients of the linear term that takes any first-type reference data point of the undersampled point, the linear term that takes any second-type reference data point of the undersampled point, and the quadratic term.

16. The device as claimed in claim 15, wherein the restoration module is configured to constructs the quadratic equation for each selected ACS by: forming pairwise combinations of all ACS within the preset first interpolation range of the selected ACS and all ACS within the preset second interpolation range, respectively substituting the two ACS of each combination into the function to obtain function values, adding the obtained function values to obtain a sum of the function values, and setting the sum of the function values as equal to the selected ACS to obtain the quadratic equation.

17. A magnetic resonance imaging system, comprising the device as claimed in claim 9.

18. One or more non-transitory media storing instructions that, when executed by one or more processors, cause the one or more processors to perform the method of claim 1.

19. An apparatus comprising: one or more processors; and memory storing instructions that, when executed by the one or more processors, cause the apparatus to perform the method of claim 1.
